(19) United States
(12) Patent Application Publication
(10) Pub. No.: US 2009/0017578 A1
(43) Pub. Date: Jan. 15, 2009

(54) Application of RFID labels

(76) Inventors: Thomas Walther, Hofheim (DE); Reinhard Baumann, Krailling (DE); Robert Weiss, Gersthofen (DE); Peer Dilling, Friedberg (DE)

Correspondence Address: COHEN, PONTANI, LIEBERMAN & PAVANE LLP, 551 FIFTH AVENUE, SUITE 1210, NEW YORK, NY, 10176, US

(21) Appl. No.: 10/589,213

(22) PCT Filed: Feb. 3, 2005
(86) PCT No.: PCT/EP05/01051

§ 371 Date: Dec. 5, 2006

(30) Foreign Application Priority Data
Feb. 13, 2004 (DE) 10 2004 007 457.7

(51) Int. Cl. H01L 21/50; H01P 11/00

(52) U.S. Cl. 438/106; 29/601; 257/E21.499

(57) ABSTRACT

Disclosed is a method for producing an RFID label with the aid of a printing process. The aim of the invention is make it easy to apply the parts required onto the label while completing the label in a simple manner. Said aim is achieved by applying at least one portion of the antenna and the resonant circuit required for the function to the printing material by means of sheet-fed offset printing or directly or indirectly with the aid of a relief printing plate. The resonant circuits or chips are applied individually or to a packaging that is to be created or filled in the same alignment once several copies of the labels have been produced on one sheet and have been separated therefrom.

### CROSS-REFERENCE TO RELATED APPLICATIONS

This is a U.S. national stage of application No. PCT/EP2005/001051, filed on 3 Feb. 2005. Priority is claimed on the following application(s): Country: Germany, Application No.: 10 2004 007 457.7, Filed: 13 Feb. 2004; the content of which is incorporated here by reference.

### BACKGROUND OF THE INVENTION

The invention pertains to a process for producing RFID labels.

The invention describes various processes for producing RFID (Radio Frequency Identification) labels, also called “smart labels”. The basis of intelligent labels (RFIDs, smart labels) is so-called transponder technology. Its great advantage lies in the wireless link between the label and the reader. This can greatly accelerate the mechanical process of data acquisition, because the reader no longer needs to be linked optically with the label. Thus, for example, the content of a box or of a whole pallet can be acquired without error. Security codes can also be stored in the smart labels, as a result of which packages cannot be falsified (e.g., pharmaceutical industry), and thefts can be clearly identified.

A system for wireless identification consists of two components: the RFID label (smart label), which is attached to the merchandise, and the read/write device, which can be used to read data from or transfer data to the label. Depending on their design, the transponders store data ranging from simple identification numbers to complex sets of data (e.g., expiration date, production site and date, sale prices, etc.). Measurement data can also be stored. A transponder usually consists of an integrated circuit, an antenna, and other passive components. Depending on the way in which power is supplied, a distinction in made between active and passive transponders. If the label has its own power supply in the form of, for example, a battery, we speak of an active system. If the transponder is supplied with power by means of an external magnetic or electrical field, the system is considered passive.

The transponder integrated circuit (IC), which is connected to the antenna of the mobile data storage medium, handles the transmission and reception of the data. In the case of passive RFID transponders, all of the intelligence and functionality are usually integrated into this circuit.

Some types also contain an on-chip resonance capacitor for an oscillating circuit, so that no other external components are required except for an antenna coil. The capacitor or capacitors required can also be produced by printing methods. Known, standard processes for the production of RFID labels include the lamination of a coated foil onto the label, the printing of the antenna by the screen printing method, and production by means of ink-jet printing.

When merchandise security labels, including RFID labels, are applied, the method used in the past has been to produce a single merchandise security element on a subelement, such as a small, self-adhering label, and then to apply this label to the merchandise, to its packaging, or to its transport packaging. Merchandise security elements can also be produced, as described above, by printing them directly onto the packaging itself. To facilitate the application of the merchandise security elements, the merchandise security elements can be applied directly to individual packages, packaging elements, or parts of the packaging. When printing packaging elements, a sheet consists of several so-called “copies”. Each copy contains the whole packaging or a part of the packaging, i.e., a packaging element. This production of several copies on one sheet requires that the copies be separated from each other afterwards. This step of separating the copies can be integrated into the process of applying the merchandise security labels. After the entire sheet has been printed, it contains the preprinted sensor elements of the merchandise security element, e.g., parts of an RFID label. The next step is to attach the parts of the individual merchandise security element which respond to external sensors; these parts can be in the form of a chip. This application step is made more difficult by the fact that the copies are arranged on the sheet in such a way as to conserve space and are thus arranged in various columns and rows.

### SUMMARY OF THE INVENTION

The object of the present invention is to provide a process for applying the required parts to a package easily and with minimal technical effort.

According to a preferred embodiment of the present invention, the process for producing an RFID label having an antenna and an oscillating circuit by using a printing process comprises the steps of providing a printable substrate, and applying at least part of at least one of the antenna and the oscillating circuit to the substrate by sheet-fed offset printing.

According to another preferred embodiment of the present invention, the process for producing an RFID label having an antenna and an oscillating circuit by using a printing process comprises the steps of providing a printable substrate, and applying at least part of at least one of the antenna and the oscillating circuit directly or indirectly to the substrate by means of a letterpress plate.

Elaborations of the invention can be derived from the various dependent claims.

### BRIEF DESCRIPTION OF THE DRAWINGS

FIG. 1 is a schematic top view of an RFID label produced by the process according to the invention;

FIG. 2 is a schematic top view of a substrate sheet comprising several RFID labels produced by the process according to the invention; and

FIG. 3 is a schematic top view of a substrate sheet comprising several divided copies of RFID labels produced by the process according to the invention.

### DETAILED DESCRIPTION OF PRESENTLY PREFERRED EMBODIMENTS

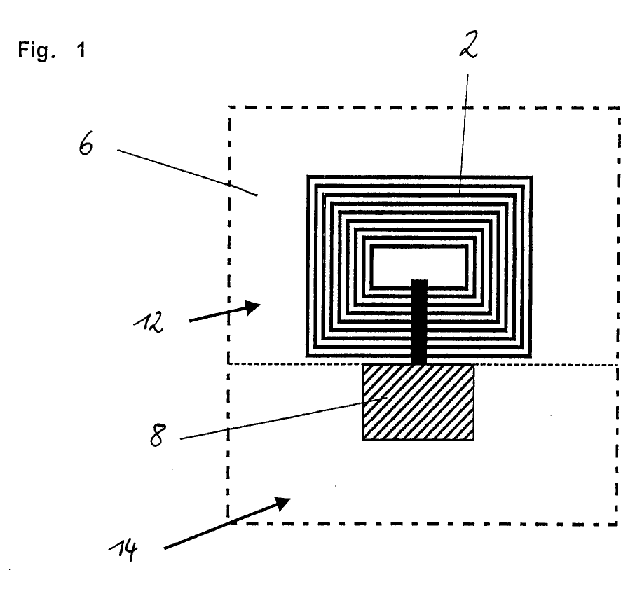

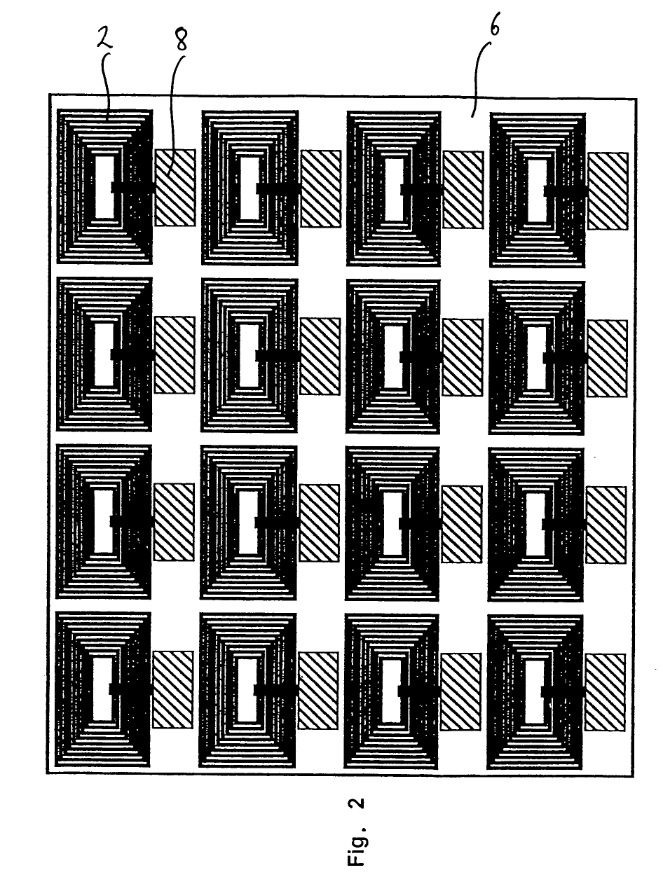

As can be seen from FIG. 1, the antenna 2 and, not shown, a part of the oscillating circuit which are required for the proper functioning of an RFID label can be applied to a section 12 of the substrate 6 which is suitable for application by use of printing technology. According to the invention, this can be done by offset printing, or directly or indirectly by means of a letterpress plate. After printing, the only further step required is to attach the IC chip 8, which usually does not have a housing, by means of a bonding or soldering process to a section 14 of the substrate 6 which is suitable for mechanical application. It is advantageous to print a multitude of antennas 2 onto one substrate 6 (FIG. 2).

With respect to the design of the antenna, the following parameters are of interest: the inductance, the coil area, the ohmic (active) resistance, and the mutual capacitance between the windings. Deviations from the characteristic values can make it impossible for contact to be established between the read/write device and the transponder. The resonance frequency must also be achieved with a high level of accuracy, which means that very strict standards are imposed on the quality of the printing.

According to a preferred embodiment of the invention, a metal ink or conductive paste is transferred via a waterless offset plate or a wet offset plate and via the printing blanket to the substrate 6 within a sheet-fed or rotary web offset press. The printed lines form the antenna 2 and possibly the entire oscillating circuit. The chip 8 is then soldered or glued on later, if necessary. The substrate 6, on which the components of the antenna 2 or of the oscillating circuit are printed, can be a fibrous material (paper, nonwoven, etc.), a fabric of natural or synthetic fibers, or a plastic film. FIG. 1 shows a schematic top view of a label produced according to the invention.

An absorbent substrate 6, e.g., paper or some other fibrous material, can be pretreated to prevent the conductive ink or paste from being absorbed. The pretreatment can involve pre-inking or the application of printer's varnish by means of a flexo press or an offset press. It is also possible to laminate a film onto the back of the label or to have the back of the label pretreated by the manufacturer. If a large amount of ink is absorbed by the substrate 6, the inductance can change as a result of the third plane. Application by means of a plate for waterless printing is preferred over wet offset, because the wetting agent required for wet offset printing can lead to corrosion of the ink. The precision of the printing is also higher. Waterless offset also makes it possible to obtain higher resolutions and finer lines.

The capacitor required to produce the oscillating circuit can be obtained by printing two lines closely together, which are connected to each other at the ends of the shorter line. Alternatively, the base line can be printed first; an insulating material is printed on top of it; and then the opposing line is printed on top of that in a third printing couple. The capacitor can also be integrated into the chip 8, as is the case in FIGS. 1 to 3. Other circuit elements such as resistors can also be printed by tapering the thickness of the lines.

In theory, the capacitor lines can be printed on both sides of the substrate 6 so that they are opposite each other. For this purpose, it is also necessary to perforate the substrate 6 beforehand so that a connection is established between the two opposing lines when the ink is applied.

Finally, the antenna 2 and the oscillating circuit can be coated with a protective coating, which protects the printed image against mechanical, chemical, and oxidative damage. Alternatively, a protective film can be applied over them.

According to another preferred embodiment of the process, an adhesive is preprinted by passing it through a printing couple. The sheet printed with the adhesive is then brought into contact with a transfer film, which has been coated with a metallic or other conductive material. At the points where the adhesive has been applied, the conductive material is separated from the carrier film and transferred to the substrate. This then forms the oscillating circuit, antenna 2, or certain parts of these components.

According to another preferred embodiment of the process, the lines of the antenna 2 and/or of the oscillating circuit can be printed by means of a flexo press. The disadvantage of this, however, is that a flexo plate can lead to blurred edges if it is not positioned precisely. These blurred edges would change the capacitance and thus cause a change in the characteristics of the oscillating circuit.

To complete the RFID label, the oscillating circuit or the entire chip 8 is added by soldering or adhesive bonding.

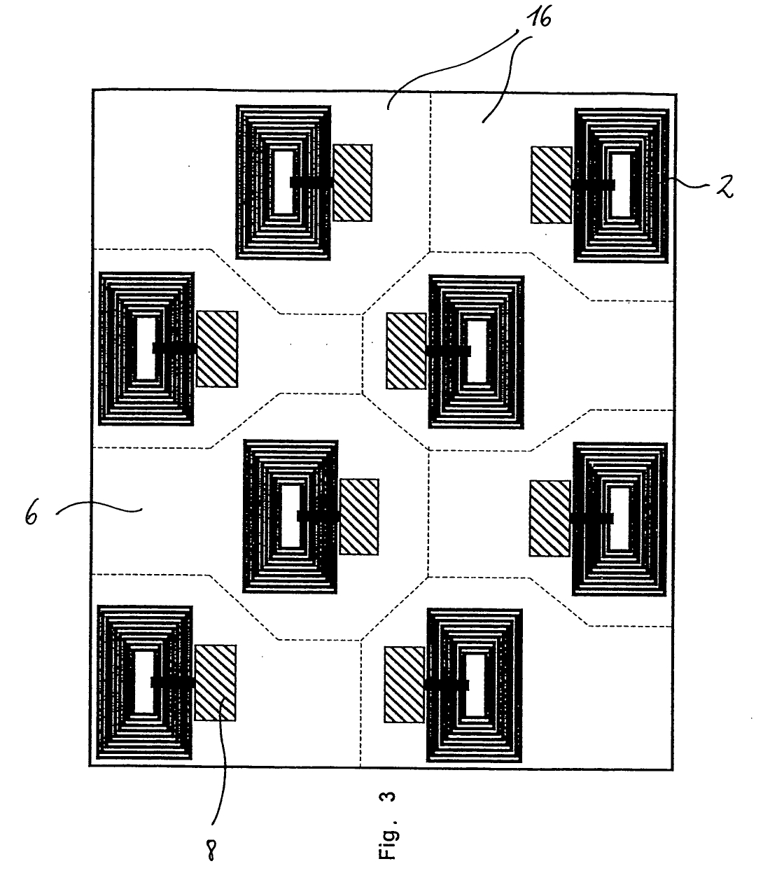

According to a preferred embodiment of the process, this final step is carried out advantageously in that the substrate 6 which is formed as a sheet is divided into individual copies 16 (FIG. 3) or blocks of copies in such a way that the elements are oriented with respect to each other in a uniform manner. When it is time to attach the chips 8, the copies 16 or blocks of copies can be fed to an applicator device in such a way that the merchandise security elements can always be processed in the same position. This greatly facilitates the application of the chips 8 to the preprinted parts of the merchandise security elements. The completed parts can then be easily applied to the packages.

It is also possible to apply the printed basic elements directly to the package. Then the RFID label can be completed in the folding box gluing machine or in the box-filling station.

The RFID labels can thus be applied to the package, to parts of the package, or to individual elements, which are themselves applied to the package or which complete the package and which carry only one RFID label.

The following procedure is proposed:

1. Several copies 16 of the antenna 2 of an RFID label are printed onto the substrate sheet 6 (see, for example, FIG. 3).

2. The copies 16 are stamped out or cut out to obtain individual copies 16.

3. The individual copies 16 are gathered and unidirectionally oriented.

4. The oscillating circuits or chips 8 are then soldered or glued onto the individual copies 16 or blocks of copies.

The oscillating circuits or chips 8 can be applied and assigned to the individual copy 16 in a separate machine. Ideally, however, the components are applied on a production line, e.g., in a folding box gluing machine or possibly in the box-filling station.

This avoids the necessity of having to transfer the articles, after they have already been put in their final packaging, to an additional labeling station for application of the merchandise security elements. Another advantage of the process is that multiple copies 16 of the antennas 2 or additional components of the oscillating circuit can be printed at once, on the same sheet. The only remaining step is then to apply the chip 8 to the individual copy 16. This makes it possible to reduce costs considerably.

1.-34. (canceled)

35. A process for producing an RFID label having an antenna and an oscillating circuit by using a printing process, comprising:
providing a printable substrate; and
applying at least part of at least one of the antenna and the oscillating circuit to the substrate by sheet-fed offset printing.

36. The process of claim 35, wherein said step of applying comprises using a conductive paste or conductive ink to print conducting tracks as part of at least one of the antenna and the oscillating circuit.

37. The process of claim 36, wherein the conductive ink is used and the conductive ink is an ink with metal particles.

38. The process of claim 36, wherein the conductive paste is used and the conductive paste contains carbon black or carbon fibers.

39. The process of claim 36, wherein said step of applying comprises applying the conductive paste or the conductive ink in a sheet-fed offset press with gripper transport.

40. The process of claim 36 wherein said step of applying comprises applying the conductive paste or the conductive ink in a rotary web offset press.

41. The process of claim 39, wherein said step of applying includes applying part of at least one of the antenna and the oscillating circuit to a rear surface of the substrate which is formed as a sheet, and flipping over the sheet in a turning device.

42. The process of claim 35, further comprising the step of applying a protective varnish or protective ink to the substrate after part of at least one of the antenna and the oscillating circuit has been printed.

43. The process of claim 42, wherein said step of applying a protective varnish or protective ink comprises transferring the protective varnish or protective ink to the substrate in a sheet-fed offset press.

44. The process of claim 42, wherein said step of applying a protective varnish or protective ink comprises transferring the protective varnish to the substrate in a flexo press with an ink chamber blade and a screen roller.

45. The process of claim 42, wherein said step of applying a protective varnish or protective ink comprises applying the protective varnish to the substrate in a flexo press with twin-roll capacity.

46. A process for producing an RFID label having an antenna and an oscillating circuit using a printing process, comprising:
providing a printable substrate; and
applying at least part of at least one of the antenna and the oscillating circuit directly or indirectly to the substrate using a letterpress plate.

47. The process of claim 46, further comprising clamping the letterpress plate onto a plate cylinder of a sheet-fed press or web-fed press, and transferring ink indirectly by way of a blanket cylinder to the substrate.

48. The process of claim 46, wherein the letterpress plate arranged in a sheet-fed or web-fed press is in direct contact with the substrate.

49. The process of claim 47, wherein the letterpress plate is used in a press which also contains offset printing units.

50. The process of claim 35, wherein the substrate is a fibrous material.

51. The process of claim 35, wherein the substrate is a film.

52. The process of claim 35, wherein the substrate is a fabric of at least one of natural and synthetic fibers.

53. The process of claim 35, further comprising, in the case of a substrate having absorbent properties, precoating, prevarnishing, or preprinting the substrate with a varnish or a pre-inking medium to reduce the absorbent properties.

54. The process of claim 53, wherein the precoating, prevarnishing, or preprinting is effected by direct letterpress.

55. The process of claim 53, wherein the precoating, prevarnishing, or preprinting is effected by a letterpress plate, acting indirectly by way of a blanket cylinder.

56. The process of claim 53, wherein the precoating, prevarnishing, or preprinting is effected by a printing unit in an offset press.

57. The process of claim 35, wherein said step of applying further comprises the steps of printing two lines with different length next to each other over a certain portion of their length, and connecting the two lines to each other at ends of a shorter line of the two lines to produce a capacitive element.

58. The process of claim 35, wherein said step of applying further comprises the steps of printing a base line, printing an insulator over part of the base line, and printing an opposing line to produce a capacitive element.

59. The process of claim 46, wherein the substrate is a fibrous material.

60. The process of claim 46, wherein the substrate is a film.

61. The process of claim 46, wherein the substrate is a fabric of at least one of natural and synthetic fibers.

62. The process of claim 46, further comprising, in the case of a substrate having absorbent properties, precoating, prevarnishing, or preprinting the substrate with a varnish or a pre-inking medium to reduce the absorbent properties.

63. The process of claim 62, wherein the precoating, prevarnishing, or preprinting is effected by direct letterpress.

64. The process of claim 62, wherein the precoating, prevarnishing, or preprinting is effected by a letterpress plate, acting indirectly by way of a blanket cylinder.

65. The process of claim 62, wherein the precoating, prevarnishing, or preprinting is effected by a printing unit in an offset press.

66. The process of claim 46, wherein said step of applying further comprises the steps of printing two lines with different length next to each other over a certain portion of their length, and connecting the two lines to each other at ends of a shorter line of the two lines to produce a capacitive element.

67. The process of claim 46, wherein said step of applying further comprises the steps of printing a base line, printing an insulator over part of the base line, and printing an opposing line to produce a capacitive element.

68. The process of claim 35, wherein the step of applying comprises applying several copies of the at least part of at least one of the antenna and the oscillating circuit to the substrate which is formed as a sheet.

69. The process of claim 35, wherein the step of applying comprises applying several copies of the at least part of at least one of the antenna and the oscillating circuit to the substrate which is formed as a sheet, each copy being used for a respective package or respective part of a package.

70. The process of claim 35, wherein the step of applying comprises applying several copies of the at least part of at least one of the antenna and the oscillating circuit to the substrate which is formed as a sheet, each copy being intended for a single RFID label.

71. The process of claim 68, further comprising the step of separating the copies on the substrate from each other.

72. The process of claim 71, wherein the copies on the substrate are separated from each other in blocks.

73. The process of claim 71, wherein the copies on the substrate are separated individually from each other.

74. The process of claim 71, further comprising the steps of uniformly orienting the separated copies or blocks of copies, and applying the oscillating circuits, further parts of the oscillating circuits, or IC chips to the oriented copies or blocks of copies.

75. The process of claim 71, further comprising the steps of attaching the separated copies to packages, and applying the oscillating circuits, further parts of the oscillating circuits, or IC chips to the attached copies.

76. The process of claim 75, wherein the step of applying the oscillating circuits, further parts of the oscillating circuits, or IC chips to the attached copies is performed during a preparation of the packages in a folding box gluing machine.

77. The process of claim 75, wherein the step of applying the oscillating circuits, further parts of the oscillating circuits, or IC chips to the copies is performed during a filling of the packages in a box-filling station.

78. The process of claim 46, wherein the step of applying comprises applying several copies of the at least part of at least one of the antenna and the oscillating circuit to the substrate which is formed as a sheet.

79. The process of claim 46, wherein the step of applying comprises applying several copies of the at least part of at least one of the antenna and the oscillating circuit to the substrate which is formed as a sheet, each copy being used for a respective package or respective part of a package.

80. The process of claim 46, wherein the step of applying comprises applying several copies of the at least part of at least one of the antenna and the oscillating circuit to the substrate which is formed as a sheet, each copy being intended for a single RFID label.

81. The process of claim 78, further comprising the step of separating the copies on the substrate from each other.

82. The process of claim 81, wherein the copies on the substrate are separated from each other in blocks.

83. The process of claim 81, wherein the copies on the substrate are separated individually from each other.

84. The process of claim 81, further comprising the steps of uniformly orienting the separated copies or blocks of copies, and applying the oscillating circuits, further parts of the oscillating circuits, or IC chips to the oriented copies or blocks of copies.

85. The process of claim 81, further comprising the steps of attaching the separated copies to packages, and applying the oscillating circuits, further parts of the oscillating circuits, or IC chips to the attached copies.

86. The process of claim 85, wherein the step of applying the oscillating circuits, further parts of the oscillating circuits, or IC chips to the copies is performed during a preparation of the packages in a folding box gluing machine.

87. The process of claim 85, wherein the step of applying the oscillating circuits, further parts of the oscillating circuits, or IC chips to the copies is performed during a filling of the packages in a box-filling station.
